(19) United States
(12) Patent Application Publication
(10) Pub. No.: US 2025/0123571 A1
(43) Pub. Date: Apr. 17, 2025

(54) FULL-WAFER METROLOGY UP-SAMPLING

(71) Applicant: NOVA LTD., Rehovot (IL)

(72) Inventors: Eitan A. ROTHSTEIN, Rehovot (IL); Harindra VEDALA, Rehovot (IL); Effi ABOODY, 7632805 (IL); Noam TAL, Mishmar Hashivaa (IL); Jacob COHEN, Rehovot (IL); Michael SHIFRIN, Rehovot (IL); Nir Kampel, Rehovot (IL); Lilach TAMAM, Rehovot (IL); Avron GER, Rehovot (IL)

(73) Assignee: NOVA LTD., Rehovot (IL)

(21) Appl. No.: 18/855,303

(22) PCT Filed: Apr. 7, 2023
(86) PCT No.: PCT/IL2023/050379

§ 371 Date: Oct. 8, 2024

Related U.S. Application Data
(60) Provisional application No. 63/328,332, filed on Apr. 7, 2022.

(51) Int. Cl. G03F 7/00

(52) U.S. Cl. CPC G03F 7/706841; G03F 7/70625; G03F 7/706833

(57) ABSTRACT

A system and methods for OCD metrology are provided including receiving training data for training an OCD machine learning (ML) model, the training data measured from multiple wafers and including multiple pairs of corresponding input and label datasets obtained from each respective wafer. The input dataset of each pair includes multiple scatterometric datasets, measured at multiple respective locations defined by a first map. The label dataset of each pair includes one or more critical dimension (CD) parameters of respective locations defined by a second map, the second map including at least one location not in the first map. The OCD ML model is then applied to a new set of scatterometric datasets, measured from locations of a new wafer, according to the first map, to generate predicted CD parameters of locations of the second map on the new wafer.

### FIELD OF THE INVENTION

The present invention relates generally to the field of optical inspection of integrated circuit wafer patterns, and in particular to algorithms for measurement of wafer pattern parameters.

### BACKGROUND

Integrated circuits (ICs) are produced on semiconductor wafers through multiple steps of depositing, altering, and removing thin layers, which build up into stacked structures on the wafers. These stacked structures, also referred to as “stacks,” “features,” may be formed in repetitive patterns, which, like diffraction gratings, have optical properties. Modern optical metrology methods for measuring critical dimensions (CDs) and material properties of these patterns exploit these optical properties, for example, by applying Rigorous Coupled Wave Analysis (RCWA) to scatterometric data to determine the CDs and material properties at a given measurement location.

Hereinbelow, CDs and material properties are also referred to as “parameters of interest” (POI), or simply as “parameters.” These parameters may include the height, width, and pitch of stacks. As described by Dixit, et al., in “Sensitivity analysis and line edge roughness determination of 28-nm pitch silicon fins using Mueller matrix spectroscopic ellipsometry-based optical critical dimension metrology,” J. Micro/Nanolith. MEMS MOEMS. 14(3), 031208 (2015), incorporated herein by reference, pattern parameters may also include: side wall angle (SWA), spacer widths, spacer pull-down, epitaxial proximity, footing/undercut, over-fill/under-fill of 2-dimentional (HKMG), 3-dimentional profile (FinFETs) and line edge roughness (LER).

Optical critical dimension (OCD) metrology employs methods of scatterometry to measure scatterometric data, that is, reflected light radiation that is indicative of optical properties of patterns. A set of scatterometric data (which may also be referred to as a scatterometric signature) may include data points of reflected irradiance versus an incident angle of radiation (which may be zeroth-order measurements). Alternatively, or additionally, scatterometric data may include spectrograms that are measures of reflected radiation intensity over a range of wavelengths or frequencies. Additional types of scatterometric data known in the art may also be applied in OCD metrology.

U.S. Pat. No. 6,476,920 to Scheiner and Machavariani, “Method and apparatus for measurements of patterned structures,” incorporated herein by reference, describes development of an “optical model” (also referred to as “physical model”). An optical model is a function (i.e., a set of algorithms) defining a relation between reflected radiation and the physical structure of a wafer. That is, optical models are theoretical models of how light is reflected from patterns with known parameters. Such optical models can therefore be applied to generate, from a set of known pattern parameters, an estimate of scatterometry data that would be measured during metrology session(s), e.g. on production wafers during HVM. Optical models can also be designed to perform the converse (or “inverse”) function, of estimating pattern parameters based on measured scatterometry data.

Optical models are commonly applied for OCD metrology during IC production to determine, based on scatterometric measurements, whether wafer patterns are being fabricated with correct parameters. Parameters of patterns on a given wafer may be measured to determine how much the parameters vary from design specifications, which may specify allowed deviations from mean values.

Machine learning (ML) techniques may also be applied to estimate pattern parameters based on scatterometry data. For example, as described in PCT patent application WO 2019/239380 to Rothstein, et al., incorporated herein by reference, a machine learning model may be trained to identify correspondences between measured scatterometry data and reference parameters.

Exemplary scatterometric tools for measuring (acquiring) scatterometry data (e.g., spectrograms) may include spectral ellipsometers (SE), spectral reflectometers (SR), polarized spectral reflectometers, as well as other optical critical dimension (OCD) metrology tools. Such tools are incorporated into OCD metrology systems currently available. One such OCD metrology system is the NOVA Prism OCD Metrology tool, commercially available from Nova Measuring Instruments Ltd. of Rehovot, Israel, which takes measurements of pattern parameters that may be at designated test sites or “in-die.” Additional methods for measuring critical dimensions (CDs) include interferometry, X-ray Raman spectrometry (XRS), X-ray diffraction (XRD), and pump-probe tools, among others. Some examples of such tools are disclosed in U.S. Pat. Nos. 10,161,885, 10,054,423, 9,184,102, and 10,119,925, and in international pending patent application publication WO2018/211505, all assigned to the Applicant and incorporated herein by reference in their entirety. Scatterometric tools configured as integrated metrology (IM) platforms enable advanced process control (APC) to monitor and control wafer to wafer variations of complex high-end CMP and Etch applications during High Volume Manufacturing (HVM) with high productivity and reliability required for the most advanced logic and memory technology nodes. Integrated metrology systems include Nova i550, i570, and ASTERA, commercially available from Nova Measuring Instruments Ltd. of Rehovot, Israel, which are integrated with processing equipment such as CMP Polishers, etc.

High accuracy methods of measuring pattern parameters that do not rely on the optical models described above include wafer measurements with equipment such as CD scanning electron microscopes (CD-SEMs), atomic force microscopes (AFMs), cross-section tunneling electron microscopes (TEMs), or X-ray metrology tools. These methods are typically more expensive and time-consuming than optical modeling methods.

Regardless of whether optical and ML models are applied to scatterometric data, the process of obtaining scatterometric data is time-consuming. On the other hand, sparse measurement of scatterometric data may be insufficient to indicate problems of wafer production. Embodiments of the present invention as disclosed hereinbelow address these shortcomings of sparse scatterometric data measurement.

### SUMMARY

Embodiments of the present invention provide systems and methods for generating machine learning models for optical critical dimension (OCD) monitoring including “up-sampling” to improve OCD resolution. Advanced wafer fabrication can benefit from more extensive sampling of critical dimension (CD) parameters, but extensive sampling conflicts with measurement cycle time goals and overall metrology tool costs. Consequently, manufacturers often use “sparse” sampling schemes that reduce monitoring delays. The systems and methods provided herein provide the CD parameters of interest by up-sampling that avoids the monitoring time delay. The result is improved OCD monitoring, with higher accuracy and robustness, without a corresponding time delay, thereby improving process control.

### BRIEF DESCRIPTION OF DRAWINGS

For a better understanding of various embodiments of the invention and to show how the same may be carried into effect, reference is made, by way of example, to the accompanying drawings. Structural details of the invention are shown to provide a fundamental understanding of the invention, the description, taken with the drawings, making apparent to those skilled in the art how the several forms of the invention may be embodied in practice. In the figures:

FIG. 1 is a block diagram of a system for generating a machine learning model for OCD metrology, by up-sampling from a sparse wafer map, in accordance with an embodiment of the present invention;

FIG. 2 is a schematic diagram of the application of a machine learning model to up-sample from a sparse wafer map to a denser wafer map, in accordance with an embodiment of the present invention;

FIG. 3 is a flow diagram depicting a process for generating a machine learning model for OCD metrology, with up-sampling from a sparse wafer map, in accordance with an embodiment of the present invention;

FIG. 4 is a schematic diagram depicting application of input and output (i.e., target) data, in the generation of a machine learning model for up-sampling from a sparse wafer map, in accordance with an embodiment of the present invention;

FIG. 5 is a schematic diagram of a neural network serving as a machine learning model for up-sampling from a sparse wafer map, in accordance with an embodiment of the present invention;

FIGS. 6A-6C are graphs validating a machine learning model for up-sampling from a sparse wafer map, in accordance with an embodiment of the present invention; and

FIG. 7 is a graph indicating a “trust” parameter that can be associated with input data for up-sampling from a sparse wafer map, in accordance with an embodiment of the present invention.

### DETAILED DESCRIPTION

Embodiments of the present invention provide systems and methods for generating machine learning (ML) models for optical critical dimension (OCD) monitoring, by training an ML model with scatterometry data, for up-sampling from a “sparse” wafer map, that is for predicting OCD parameters not measured directly from a sparse set of wafer parameter measurements.

Although advanced OCD metrology equipment can provide fast and non-destructive measurements of critical dimensions, manufacturers generally take optical metrology measurements from only a sparse subset of the dies on a wafer (typically ˜25%), in order to meet cycle time goals. Wafer sampling plans may be carefully designed to acquire measurements from all wafer quadrants and known radii of interest, but useful details indicating processing variations may still be missed. These details can include process specific within-wafer (WiW) profiles, topography variations within die regions of interest, or process-chamber specific WiW profiles. Furthermore, while supporting process changes, qualifying new equipment, and for excursion detection and recovery, it is often necessary to acquire a larger number of measurements. Up-sampling from measurements taken from a sparse wafer map, as provided by methods and systems of the present invention, achieves the advantages of acquiring more wafer measurements without impeding manufacturing throughput.

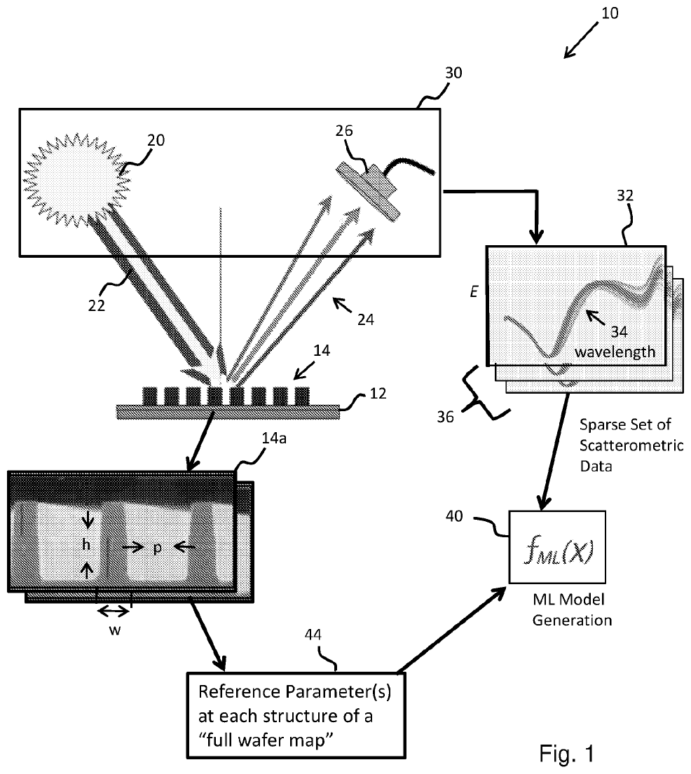

FIG. 1 is a schematic diagram of a system 10 for generating a machine learning model for OCD metrology, in accordance with an embodiment of the present invention.

The system 10 may operate within a production line (not shown) for production and monitoring of one or more wafers 12. As indicated, wafers 12 include patterns 14 (also referred to herein as “structures”). These patterns have critical dimensions (CDs), or “parameters,” which may include height (“h”), width (“w”), and pitch (“p”), as indicated in the pattern enlargement 14a, as well as other parameters described in the Background above. Typically, a single wafer includes multiple dies, which are designed with the same patterns (i.e., the same pattern design). For each pattern (“point of interest”) in each die, a set of multiple parameters may be measured.

Manufacturing variations cause slight variations in the parameters of measurement locations between wafers and across a single wafer. These variations cause variations in measured scatterometry data. During typical monitoring, a scatterometry dataset is measured at a measurement location defined by a wafer map, typically for the same pattern in each of multiple dies. Optical models are then applied to the scatterometry dataset to determine a set of one or more POIs (i.e., CD parameters). Scatterometry datasets are also written herein as vectors [symbol] , and a set of one or more CD parameters at a given measurement location is written as a vector \vec{p}. A set of all scatterometry datasets measured from a given wafer is written as a set S, and a set of \vec{p} vectors, i.e., CD parameters measured at each of multiple common measurement locations in multiple respective dies of a wafer, is referred to as a set P.

The system 10 includes a light source 20, which generates a beam of light 22 of a predetermined wavelength range. During the monitoring process, the beam of light 22 is reflected from a wafer pattern 14 (indicated as reflected, or “scattered,” light 24) towards a spectrophotometric detector 26. In some configurations, the light source and spectrophotometric detector (e.g., ellipsometer or a spectrophotometer) are included in an OCD metrology system 30. The construction and operation of the metrology system 30 may be of any known kind, for example, such as the type disclosed in U.S. Pat. No. 5,517,312, 6,657,736, and 7,169,015, and in international pending patent application publication WO2018/211505, all assigned to the Applicant and incorporated herein by reference in their entirety. Typically the metrology system 30 includes additional components, not shown, such as light directing optics, which may include a beam deflector having an objective lens, a beam splitter and a mirror. Additional components of such systems may include imaging lenses, polarizing filter(s), variable aperture stops, and motors. Operation of such elements is typically automated by computer controllers, which may include I/O devices and which may also be configured to perform data processing tasks, such as generating scatterometry data 32.

The scatterometry data 32 generated by the metrology system 30 may include a spectrogram 34, which may be represented in vector form, whose data points are measures of reflected light intensity “E” at different light wavelengths. Scatterometry data may also or alternatively be a mapping of reflected irradiance vs. incident angle. In typical OCD metrology, the range of light that is measured may cover the visible light spectrum and may also include wavelengths in ultraviolet and infrared regions. A typical spectrogram output for OCD metrology may have 245 data points covering a wavelength range of 200 to 970 nm.

As described above, a scatterometric dataset is measured from each point of a predefined map of a wafer. All measurement locations of the map are copies of a given pattern and ideally would have the same CD parameters. In actual manufacturing, processing conditions vary over the surface of a wafer, and the variation between scatterometric datasets of the different measurement locations is indicative of the differing CD parameters of the measurement locations.

In embodiments of the present invention, sets of scatterometric data from a “sparse” map of measurement locations on a wafer are applied to train an ML model 40 to improve OCD measurement resolution, that is, to predict, on the basis of the sparse measurements, parameter values at a larger number of measurement locations on the wafer. Hereinbelow, the process of predicting values of a higher resolution map from a sparse map is also referred to as “up-sampling.” It should be understood that a “sparse map” is defined as being a map having fewer measurement locations than the target, more dense map. Hereinbelow, the denser map is also referred to herein as a “full wafer map” (FWM), but it is also to be understood that a map referred to herein as a FWM may cover less than 100% of dies of a wafer (and conversely may also include more measurement locations than dies). In typical metrology practice for HVM, e.g. using Integrated Metrology platform(s) the sparse map may be a typical, high-throughput map indicating measurement locations for perhaps 20% to 30% of dies of a wafer design, while the FWM may cover 80% to 100%. However, it is to be understood that the present invention applies to a wide range of sparse and dense maps, where the difference between the maps may be a single measurement location.

The ML model may be based on ML tools known in the art, such as neural networks, random forest, or any type of ML regression algorithms. It may include known methods to avoid overfit, such as regularizations, model ensembles or smart feature extraction and selection. Reference parameters 44 from a denser wafer map may be used as target labels for ML training. The reference parameters may be acquired from measurement locations of one or more wafers by the same OCD spectroscopy used for acquiring the set of scatterometric data 36, or by other means known in the art, such as CD-SEM, AFM, TEM, X-ray metrology. After training, the ML model 40 is used to predict pattern parameters based on sets of scatterometric data. The predicted pattern parameters may then be applied, for example, in the monitoring of wafer production.

The ML model 40 may operate independently of the metrology system 30 or may be integrated with the metrology system.

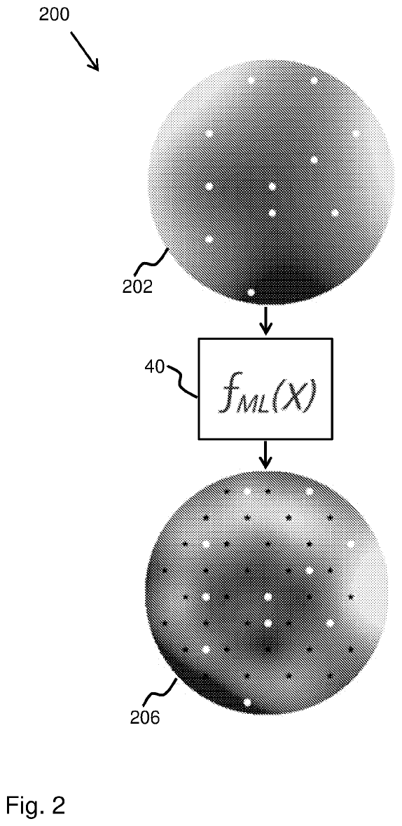

FIG. 2 is a schematic diagram of the process by which the ML model 40 up-samples from a sparse wafer map to a denser wafer map. Sparse map 202 indicates white dots at positions that are measured by spectroscopy. Dense map 206 shows the sparse measurements as white dots, with extrapolated measurements obtained by the ML model indicated as black dots. Backgrounds of both maps indicate shaded contour maps for a given CD parameter. The contours were generated by interpolation between the measured points for the sparse map, and by interpolation between the measured and predicted points for the dense map. Interpolation was performed by a simple radial basis function with a cubic spline interpolation. As shown, the contour map is significantly more detailed (i.e., has a higher resolution) for the dense map. The high-resolution data provided by the ML model reveal enhanced visibility of POI variability. The greater visibility that could help to provide early detection for process and hardware performance and contribute to successful fulfillment of key deliverables.

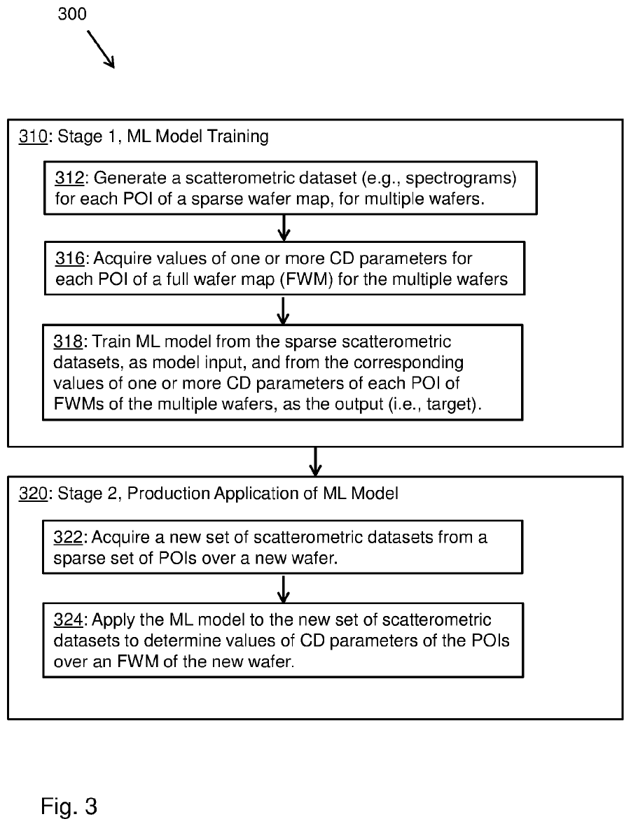

FIG. 3 is a flow diagram depicting a computer-implemented process 300 for generating a machine learning model for OCD metrology, with up-sampling from a sparse wafer map, in accordance with an embodiment of the present invention. Process 300 includes two stages, a training stage 310 for generating the ML model 40, and a production stage 320, implemented by the ML model 40, as described above.

A first step 312 of the ML training stage includes generating (i.e., measuring) scatterometric datasets (e.g., spectrograms) for each measurement location of a sparse wafer map, for multiple wafers. The scatterometric datasets measured from each wafer serve as input data for training.

A second step 316 of training includes acquiring (e.g., measuring and/or calculating) corresponding label training data (i.e., target data) for each wafer, the label training data being the value of one or more CD parameters for each measurement location of a second, typically denser map, e.g., a full wafer map (FWM), for the multiple wafers. It is to be understood that in some implementations, the second map is simply different from the first map in that it includes at least one location not in the first map, while the first map is typically, but not necessarily a subset of the second map. In some implementations, the CD parameters of the second map are obtained from scatterometric datasets, and given that the first map is a subset of the second map, the scatterometric datasets associated with the first map are then applied as the input training datasets.

At a step 318, the ML model is then trained with the input and corresponding label datasets acquired from each wafer.

Once the ML model is generated, it is applied in the production stage 320. At a step 322, a new set of scatterometric datasets is measured from a sparse set of measurement locations over a new wafer. The ML model is then applied to the new set of scatterometric datasets at a step 324, to determine values of CD parameters of the measurement locations over an FWM of the new wafer e.g. during HVM using Integrated Metrology platform(s). Generated ML model could be deployed on Integrated Metrology tool that is used for APC during HVM.

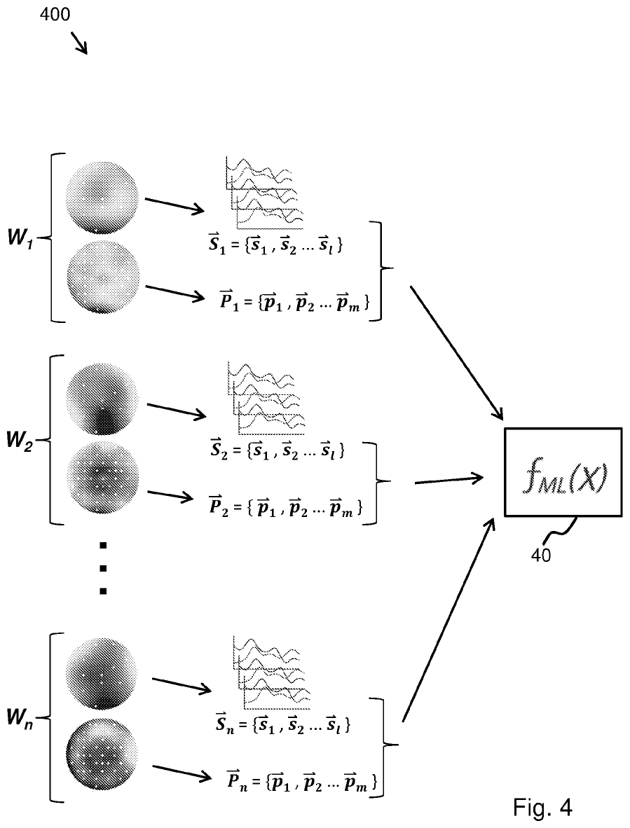

FIG. 4 is a graphical view of the steps for generating the ML model 40. A set of n wafers is depicted, shown as W₁ through Wₙ, with a sparse map and a dense (FWM) shown for each. Scatterometric datasets are measured from the measurement locations of the sparse map, indicated in the figure both as a set of spectrograms and by equations of the form:

$${S}_{i} = \{ {\vec{s}}_{1} , {\vec{s}}_{2} … {\vec{s}}_{l} \} ,$$

where each lowercase [symbol] vector represents a scatterometric dataset from a single measurement location, the uppercase S representing the set of all scatterometric datasets of the sparse map of the wafer. The sparse set is indicated as having/number of datasets.

CD parameters at all measurement locations of the dense map are indicated by equations of the form:

$${P}_{i} = \{ {\vec{p}}_{1} , {\vec{p}}_{2} … {\vec{p}}_{m} \} ,$$

the CD parameters of each measurement location indicated by lowercase [symbol] vectors, the dense map indicated as having m measurement locations, where m>l. As indicated, the ML model 40 is trained from the n pairs of corresponding S and P.

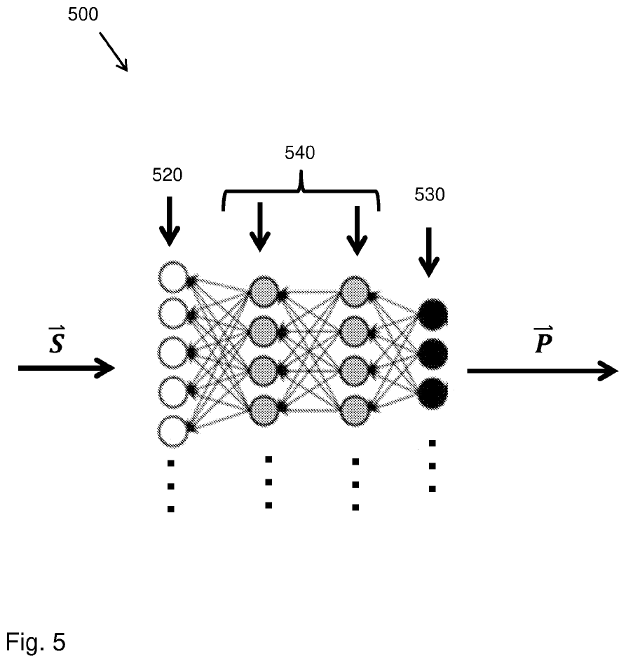

FIG. 5 is a schematic diagram of a neural network 500 serving as a machine learning model for up-sampling from a sparse wafer map. A set S of scatterometric datasets from a sparse wafer map is fed to input nodes 520. The total number of input nodes 520 is equal to the number of data points of the set S, which is equal to the number of measurement locations, l, multiplied by the number of data points of each scatterometric dataset, d (e.g., 245 data points, as described above). This number of input nodes, l×d, transfers to m×k output nodes 530 for a target set P of k predicted CD parameters at each predicted location of a dense wafer map. One or more hidden layers 540 connect the input and output nodes.

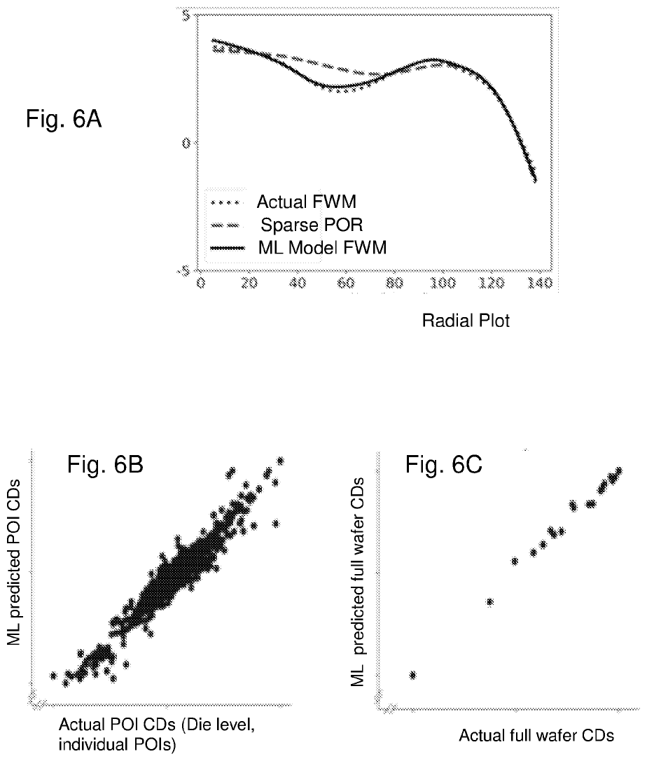

FIGS. 6A-6C are graphs validating a machine learning model for up-sampling from a sparse wafer map, in accordance with an embodiment of the present invention. CD measurement data is typically consolidated for visual analysis. Such consolidation may take the form of radial profiles, contour maps, and various statistical measures such as wafer mean and WiW standard deviation. FIG. 6A shows that a radial graph, with ML-predicted CD values, are much closer to a radial graph of actual CD values than a radial graph of sparse CD values (with interpolation between measurement locations to determine radial values).

FIGS. 6B and 6C show correlation statistics between actual FWM CD measurements and ML-predicated values, for both die-level (FIG. 6B) and wafer-level measurements (FIG. 6C). As can be seen, the correlations each show a nearly linear fit with slopes close to unity.

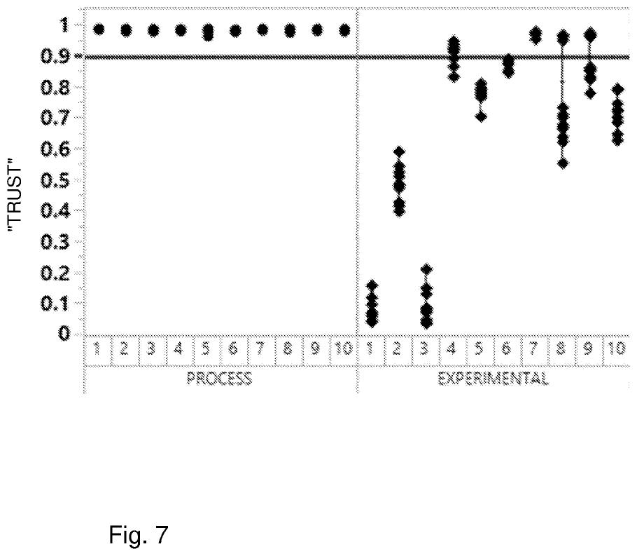

FIG. 7 is a graph indicating a “trust” score that can be associated with input data for up-sampling from a sparse wafer map. The trust score is a confidence measure for the predicted results, which is based on a measure of “closeness” (i.e., an inverse of “distance”) of the input data to the range spanned by the input data of the training set. When the input data, i.e., a set S of scatterometric datasets has a trust score of greater than, for example, 90%, the results may be considered reliable. The trust score may be based, for example, on a merit function distance between a function and a set of functions, as described in international patent application W02021140515, titled, “Detecting outliers and anomalies for OCD metrology machine learning,” the merit function description therein being incorporated herein by reference.

The table in the figure presents trust scores determined from in-line, process-of-record (POR) wafers (indicated as “PROCESS”) compared with trust scores of experimental wafers that have undergone stack changes (EXPERIMENTAL). The in-line process data show trust scores of well over 90% for most sites. (A few points, not shown, that fell below 0.90 were edge-die locations that exhibited larger stack variability than those contained in the training set.) The experimental data show trust scores predominantly below 90%, indicating that the process stacks of these wafers are measurably different than those that produced the training set. These results indicate that the ML-predicted solutions are sensitive to in-line process perturbations. As such, the trust score is a quality metric capable of alerting users to wafer aberrations, or as an indicator of when additional ML training data is required.

In short, it is important to engineer sampling schemes to adequately capture all radial variations and spatial variability patterns to ensure the metrics are truly representative of the process. In addition, because different process tools during the process flow have dissimilar spatial variability signatures, sampling schemes at different process steps should be modified accordingly. Due to cycle time constraints, sparse measurements are often employed, but the result is that defects may be exposed only at end-of-line (EOL) testing. Up-sampling, as disclosed herein, emulates full wafer sampling, enhancing visibility of potential problems, leading to improved process control.

It is to be understood that processing elements shown or described herein are preferably implemented by one or more computers in computer hardware and/or in computer software embodied in a non-transitory, computer-readable medium in accordance with conventional techniques, such as employing a computer processor, a memory, I/O devices, and a network interface, coupled via a computer bus or alternate connection arrangement.

Unless otherwise described, the terms “processor” and “device” are intended to include any processing device, such as, for example, one that includes a CPU (central processing unit) and/or other processing circuitry (e.g., GPUs), and may refer to more than one processing device. Various elements associated with a processing device may be shared by other processing devices.

The term “memory” as used herein is intended to include memory associated with a processor or CPU, such as, for example, RAM, ROM, a fixed memory device (e.g., hard drive), a removable memory device (e.g., diskette, tapes), flash memory, etc. Such memory may be considered a computer readable storage medium.

In addition, phrases “input/output devices” or “I/O devices” may include one or more input devices (e.g., keyboard, mouse, scanner, HUD, etc.) for entering data to the processing unit, and/or one or more output devices (e.g., speaker, display, printer, HUD, AR, VR, etc.) for presenting results associated with the processing unit.

Embodiments of the invention may include a system, a method, and/or a computer program product. The computer program product may include a computer readable storage medium (or media) having computer readable program instructions thereon for causing a processor to carry out aspects of the invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), Blue-Ray, magnetic tape, Holographic Memory, a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. A network adapter card or network interface in each computing/processing device may receive computer readable program instructions from the network and forwards the computer readable program instructions for storage in a computer readable storage medium within the respective computing/processing device.

Computer readable program instructions for carrying out operations of the invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Java, Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the invention.

Where aspects of the invention are described herein with reference to flowchart illustrations and/or block diagrams of methods, apparatus (systems), and computer program products according to embodiments of the invention, it will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

Any flowchart and block diagrams included herein illustrate the architecture, functionality, and operation of possible implementations of systems, methods, and computer program products according to various embodiments of the invention. In this regard, each block in the flowchart or block diagrams may represent a module, segment, or portion of instructions, which may include one or more executable instructions for implementing the specified logical function(s). In some alternative implementations, the functions noted in the block may occur out of the order shown herein. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

### EXAMPLES

Examples of the present invention may include the following configurations.

Example 1 is a method for optical critical dimension (OCD) metrology, which includes the following steps.
1) Training data is received for training an OCD machine learning (ML) model, the training data measured from multiple wafers and including multiple pairs of corresponding input and label datasets obtained from each respective wafer. The input dataset of each pair includes multiple scatterometric datasets, measured at multiple respective locations defined by a first map of each wafer. The label dataset of each pair includes one or more critical dimension (CD) parameters of multiple respective locations defined by a second map of each wafer, the second map including at least one location not in the first map
2) The input and label pairs of training datasets are applied to generate the OCD ML model.
3) The OCD ML model is then applied to a new set of scatterometric datasets, measured from locations of a new wafer, according to the first map, to generate predicted CD parameters of locations of the second map on the new wafer.

Example 2 is a method including the steps of example 1, further limited by the first map being a subset of the second map.

Example 3 is a method including the steps of example 2, further limited in that receiving the training data includes receiving, for each wafer, the scatterometric datasets for the first map as well as additional scatterometric datasets for each second map location not included in the first map, and determining, from all the scatterometric datasets of the second map, the label dataset of CD parameters for each wafer.

Example 4 is a method including the steps of any of examples 1 to 3, further including a step of measuring a distance of the new set of scatterometric datasets from a range of the scatterometric datasets of the input training dataset to validate a trust score of the prediction of CD parameters of the locations of the second map on the new wafer.

Example 5 is a method including the steps of any of examples 1 to 4, further including a step of calculating a radial plot of the predicted CD parameters of the new wafer to identify a process control problem and responsively issue a user alert.

Example 6 is a method including the steps of any of examples 1 to 5, further limited in that the one or more CD parameters of the label dataset are obtained by applying an optical model to scatterometric datasets obtained at locations of the second map.

Example 7 is a method including the steps of any of examples 1 to 5, further limited in that the one or more CD parameters of the label dataset are obtained by applying a second ML model to scatterometric datasets obtained at locations of the second map.

Example 8 is a method including the steps of any of examples 1 to 5, further limited in that the one or more CD parameters of the label dataset are obtained from one or more of a CD scanning electron microscope (CD-SEM), an atomic force microscope (AFM), a cross-section tunneling electron microscope (TEM), or an X-ray metrology tool.

Example 9 is a method including the steps of any of examples 1 to 8, further limited in that each scatterometry dataset is a spectrogram.

Example 10 is a method including the steps of any of examples 1 to 9, further limited in that the scatterometry datasets are measured by one or more instruments including spectral ellipsometers (SE), spectral reflectometers (SR), and polarized spectral reflectometers.

Example 11 is a method including the steps of any of examples 1 to 10, further limited in that the OCD ML model is one or a neural network or a random forest algorithm.

Example 12 is a system for optical critical dimension (OCD) metrology compromising a processor having non-transient memory, the memory including instructions that when executed by the processor cause the processor to implement steps of any of examples 1-11.

Example 13 is a non-transitory, machine-accessible storage medium having instructions stored thereon, the instructions, when executed by a machine, causing the machine to implement steps of steps of any of examples 1-11.

Verification of the trained (up-sampled) model can be done by time-based triggering of real full wafer map collected on same equipment (integrated metrology) or on standalone system, alternatively the trigger can be performance based on predicted WiW/Within Zone variation and or confidence indicator of the model.

1. A method for optical critical dimension (OCD) metrology, comprising:
receiving training data for training an OCD machine learning (ML) model, the training data measured from multiple wafers and including multiple pairs of corresponding input and label datasets obtained from each respective wafer,
wherein the input dataset of each pair includes multiple scatterometric datasets, measured at multiple respective locations defined by a first map of each wafer, and
wherein the label dataset of each pair includes one or more critical dimension (CD) parameters of multiple respective locations defined by a second map of each wafer, the second map including at least one location not in the first map;
applying the input and label pairs of training datasets to generate the OCD ML model; and
applying the OCD ML model to a new set of scatterometric datasets, measured from locations of a new wafer, according to the first map, to generate predicted CD parameters of locations of the second map on the new wafer.

2. The method of claim 1, wherein the first map is a subset of the second map.

3. The method of claim 2, wherein receiving the training data comprises receiving, for each wafer, the scatterometric datasets for the first map as well as additional scatterometric datasets for each second map location not included in the first map, and determining, from all the scatterometric datasets of the second map, the label dataset of CD parameters for each wafer.

4. The method of claim 1, further comprising measuring a distance of the new set of scatterometric datasets from a range of the scatterometric datasets of the input training dataset to validate a trust score of the prediction of CD parameters of the locations of the second map on the new wafer.

5. The method of claim 1, further comprising calculating a radial plot of the predicted CD parameters of the new wafer to identify a process control problem and responsively issue a user alert.

6. The method of claim 1, wherein the one or more CD parameters of the label dataset are obtained by applying an optical model to scatterometric datasets obtained at locations of the second map.

7. The method of claim 1, wherein the one or more CD parameters of the label dataset are obtained by applying a second ML model to scatterometric datasets obtained at locations of the second map.

8. The method of claim 1, wherein the one or more CD parameters of the label dataset are obtained from one or more of a CD scanning electron microscope (CD-SEM), an atomic force microscope (AFM), a cross-section tunneling electron microscope (TEM), or an X-ray metrology tool.

9. The method of claim 1, wherein each scatterometric dataset is a spectrogram.

10. The method of claim 1, wherein the scatterometric datasets are measured by one or more instruments including spectral ellipsometers (SE), spectral reflectometers (SR), and polarized spectral reflectometers.

11. The method of claim 1, wherein the OCD ML model is one or a neural network or a random forest algorithm.

12. A system for optical critical dimension (OCD) metrology compromising a processor having non-transient memory, the memory including instructions that when executed by the processor cause the processor to implement steps of:
receiving training data for training an OCD machine learning (ML) model, the training data measured from multiple wafers and including multiple pairs of corresponding input and label datasets obtained from each respective wafer,
wherein the input dataset of each pair includes multiple scatterometric datasets, measured at multiple respective locations defined by a first map of each wafer, and
wherein the label dataset of each pair includes one or more critical dimension (CD) parameters of multiple respective locations defined by a second map of each wafer, the second map including at least one location not in the first map;
applying the input and label pairs of training datasets to generate the OCD ML model; and
applying the OCD ML model to a new set of scatterometric datasets, measured from locations of a new wafer, according to the first map, to generate predicted CD parameters of locations of the second map on the new wafer.

13. A non-transitory, machine-accessible storage medium having instructions stored thereon, the instructions, when executed by a machine, causing the machine to implement steps of:
receiving training data for training an optical critical dimension (OCD) machine learning (ML) model, the training data measured from multiple wafers and including multiple pairs of corresponding input and label datasets obtained from each respective wafer,
wherein the input dataset of each pair includes multiple scatterometric datasets, measured at multiple respective locations defined by a first map of each wafer, and
wherein the label dataset of each pair includes one or more critical dimension (CD) parameters of multiple respective locations defined by a second map of each wafer, the second map including at least one location not in the first map;
applying the input and label pairs of training datasets to generate the OCD ML model; and
applying the OCD ML model to a new set of scatterometric datasets, measured from locations of a new wafer, according to the first map, to generate predicted CD parameters of locations of the second map on the new wafer.
